(19) United States
(12) Patent Application Publication
(10) Pub. No.: US 2024/0234191 A1
(43) Pub. Date: Jul. 11, 2024

(54) METHOD FOR MANUFACTURING SUPPORT ASSEMBLY AND METHOD FOR MANUFACTURING MICRO LED DISPLAY

(71) Applicant: CHONGQING KONKA OPTOELECTRONICS TECHNOLOGY CO., LTD., Chongqing (CN)

(72) Inventors: Guangchao DAI, Chongqing (CN); Feifan MA, Chongqing (CN); Zichuan WANG, Chongqing (CN)

(21) Appl. No.: 18/615,348

(22) Filed: Mar. 25, 2024

Related U.S. Application Data
(63) Continuation of application No. PCT/CN2021/127067, filed on Oct. 28, 2021.

(51) Int. Cl. H01L 21/683; H01L 25/075; H01L 33/38; H01L 33/46

(52) U.S. Cl. CPC H01L 21/6835; H01L 25/0753; H01L 33/38; H01L 33/46; H01L 2221/68354; H01L 2221/68368; H01L 2221/68386; H01L 2933/0016; H01L 2933/0025

(57) ABSTRACT

A method for manufacturing a support assembly and a method for manufacturing a micro light-emitting diode (LED) display are provided. The method for manufacturing the support assembly includes: forming an adhesive layer on a micro LED and/or a transient substrate; transferring the micro LED to the transient substrate, where the micro LED is bonded to the transient substrate through the adhesive layer; and forming the support assembly by etching the adhesive layer, where the support assembly is in a mesh shape and surrounds the micro LED.

### CROSS-REFERENCE TO RELATED APPLICATION(S)

This application is a continuation of International Application No. PCT/CN2021/127067, filed Oct. 28, 2021, the disclosure of which is hereby incorporated by reference in its entirety.

### TECHNICAL FIELD

This application relates to the field of semiconductor manufacturing technology, and particularly to a method for manufacturing a support assembly and a method for manufacturing a micro light-emitting diode (LED) display.

### BACKGROUND

Micro light-emitting diode (LED) displays involve a new generation of display technology. Compared with liquid-crystal displays (LCD), the micro LED displays have advantages of higher brightness, higher luminous efficiency, and lower power consumption.

During transferring of a micro LED, the micro LED can be transferred to a display substrate through electrostatic force, van der Waals force, magnetic force, laser selective transfer, fluid transfer, direct transfer printing, or other methods. In selectively picking up the micro LED, since the micro LED is bonded to a substrate through an adhesive, the adhesive needs to be etched before picking up the LED with a transfer structure, so as to facilitate pickup of the micro LED. However, an etching width cannot be controlled precisely when etching the adhesive, which is prone to cause damage of the micro LED, and further affect yield of mass transfer.

### SUMMARY

The disclosure provides a method for manufacturing a support assembly. The support assembly includes a first support structure. The method for manufacturing the support assembly includes: forming an adhesive layer on a micro light-emitting diode (LED) and/or a transient substrate; transferring the micro LED to the transient substrate, where the micro LED is bonded to the transient substrate through the adhesive layer; and forming the support assembly by etching the adhesive layer, where the support assembly is in a mesh shape and surrounds the micro LED.

Based on the same inventive concept, the disclosure further provides a method for manufacturing a micro LED display. The method for manufacturing the micro LED display includes: providing a substrate; forming a plurality of micro LEDs on the substrate; transferring the micro LEDs to a transient substrate, where the micro LEDs are bonded to the transient substrate through an adhesive layer; forming a support assembly by etching the adhesive layer, where the support assembly is in a mesh shape and surrounds the micro LEDs; and transferring, with a transfer structure, the micro LEDs to a display substrate.

### BRIEF DESCRIPTION OF THE DRAWINGS

In order to describe technical solutions of implementations of the disclosure more clearly, the following will give a brief description of accompanying drawings used for describing the implementations. Apparently, accompanying drawings described below are merely some implementations of the disclosure. Those of ordinary skill in the art can also obtain other accompanying drawings based on the accompanying drawings described below without creative efforts.

FIG. 1 is a flowchart illustrating a method for manufacturing a micro light-emitting diode (LED) display in the disclosure.

FIG. 2 is a structural diagram illustrating a first photoresist layer formed on a semiconductor epitaxial layer in the disclosure.

FIG. 3 is a structural diagram illustrating a recess formed in the semiconductor epitaxial layer in the disclosure.

FIG. 4 is a top view of FIG. 3.

FIG. 5 is a structural diagram illustrating a second photoresist layer formed on the semiconductor epitaxial layer in the disclosure.

FIG. 6 is a structural diagram illustrating a groove formed in the semiconductor epitaxial layer in the disclosure.

FIG. 7 is a top view of FIG. 6.

FIG. 8 is a schematic structural diagram illustrating a third photoresist layer in the disclosure.

FIG. 9 is a schematic structural diagram illustrating a transparent conductive layer in the disclosure.

FIG. 10 is a top view of FIG. 9.

FIG. 11 is a schematic structural diagram illustrating a fourth photoresist layer in the disclosure.

FIG. 12 is a schematic structural diagram illustrating a reflective layer in the disclosure.

FIG. 13 is a top view of FIG. 12.

FIG. 14 is a schematic structural diagram illustrating a fifth photoresist layer in the disclosure.

FIG. 15 is a schematic structural diagram illustrating electrodes in the disclosure.

FIG. 16 is a top view of FIG. 15.

FIG. 17 is a schematic structural diagram illustrating a first adhesive layer in the disclosure.

FIG. 18 is a schematic structural diagram illustrating a second adhesive layer in the disclosure.

FIG. 19 is a schematic structural diagram illustrating a micro LED transferred to a transient substrate in the disclosure.

FIG. 20 is a schematic structural diagram illustrating a micro LED after the substrate is peeled off in the disclosure.

FIG. 21 is a schematic structural diagram illustrating a first support structure in the disclosure.

FIG. 22 is a schematic diagram illustrating mass transfer in the disclosure.

FIG. 23 is a schematic structural diagram illustrating a support layer in the disclosure.

FIG. 24 is a schematic structural diagram illustrating a second support structure in the disclosure.

FIG. 25 is a schematic structural diagram illustrating the second adhesive layer formed on the second support structure in the disclosure.

FIG. 26 is a schematic structural diagram illustrating the micro LED transferred to the transient substrate in another implementation of the disclosure.

FIG. 27 is a schematic structural diagram illustrating the micro LED after the substrate is peeled off in another implementation of the disclosure.

FIG. 28 is a schematic structural diagram illustrating the first support structure and the second support structure in the disclosure.

FIG. 29 is a schematic diagram illustrating mass transfer in another implementation of the disclosure.

FIG. 30 is a schematic structural diagram illustrating a micro LED display in the disclosure.

Description of reference signs: 10 substrate; 100 micro LED; 100a red micro LED; 100b green micro LED; 100c blue micro LED; 11 semiconductor epitaxial layer; 111 first semiconductor layer; 112 light-emitting layer; 113 second semiconductor layer; 114 recess; 115 groove; 116 transparent conductive layer; 117 reflective layer; 118 first conductive channel; 119 second conductive channel; 120 electrode; 121 first electrode; 122 second electrode; 21 first photoresist layer; 22 second photoresist layer; 23 third photoresist layer; 24 fourth photoresist layer; 25 fifth photoresist layer; 201 first opening; 202 second opening; 203 third opening; 204 fourth opening; 205 fifth opening; 206 sixth opening; 207 seventh opening; 30 transient substrate; 31 adhesive layer; 311 first adhesive layer; 312 second adhesive layer; 313 first support structure; 314 second support structure; 315 support layer; 40 transfer structure; 50 display substrate; 501 base substrate; 502 circuit layer, 503 planarization layer, 504 protective layer, 505 protective substrate.

### DETAILED DESCRIPTION

In order to facilitate understanding of the disclosure, the disclosure will be described fully below with reference to accompanying drawings. The accompanying drawings illustrate exemplary implementations of the disclosure. However, the disclosure may be implemented in many different forms and is not limited to the implementations described herein. Rather, these implementations are provided to achieve a thorough and complete understanding of disclosed contents of the disclosure.

Unless otherwise defined, all technical and scientific terms herein have the same meaning as commonly understood by one of ordinary skill in the technical field to which the disclosure belongs. The terms herein are merely for the purpose of describing implementations of the disclosure, which are not intended to limit the disclosure.

It is to be understood that in the description of the disclosure, the terms indicating orientation or positional relationship such as “center”, “upper”, “lower”, “front”, “back”, “left”, “right”, etc. are based on orientation or positional relationship illustrated in the accompanying drawings and only for convenience of describing the disclosure and simplifying the description, but does not indicate or imply that the device or component referred to must have a specific orientation, be constructed and operated in a specific orientation, and therefore cannot be construed as a limitation of the disclosure. In addition, the terms “first” and “second” are for descriptive purposes only, and should not be understood as indicating or implying relative importance.

Hereinafter, embodiments of the present disclosure will be described in detail.

According to implementations of the disclosure, a method for manufacturing a support assembly is provided. The support assembly includes a first support structure. The method for manufacturing the support assembly includes: forming an adhesive layer on a micro light-emitting diode (LED) and/or a transient substrate; transferring the micro LED to the transient substrate, where the micro LED is bonded to the transient substrate through the adhesive layer; and forming the support assembly by etching the adhesive layer, where the support assembly is in a mesh shape and surrounds the micro LED.

In some implementations, the adhesive layer is made of organic silicide.

In some implementations, a silicon content of the adhesive layer ranges from 20% to 85%.

In some implementations, the adhesive layer is made of materials containing groups of carbon, hydrogen, and nitrogen.

In some implementations, the support assembly includes a first support structure, and forming the support assembly by etching the adhesive layer includes: forming the first support structure of the support assembly by etching the adhesive layer.

In some implementations, forming the first support structure of the support assembly by etching the adhesive layer includes: forming the first support structure by dry etching the adhesive layer with an etching gas, where the etching gas is oxygen or chlorine.

In some implementations, the first support structure is made of silicon oxide.

In some implementations, the support assembly further includes a second support structure, and the method for manufacturing the support assembly further includes: forming an oxide layer on the transient substrate; and forming the second support structure by etching the oxide layer, where the second support structure has a radial size smaller than a distance between two electrodes of the micro LED, and has a height greater than a height of the electrodes.

In some implementations, the second support structure is located between the two electrodes of the micro LED when the micro LED is bonded to the transient substrate.

In some implementations, the second support structure is made of silicon oxide.

In some implementations, the second support structure is spaced apart from the micro LED by a preset distance when the micro LED is bonded to the transient substrate.

According to implementations of the disclosure, a method for manufacturing a micro LED display is provided. The method for manufacturing the micro LED display includes: providing a substrate; forming a plurality of micro LEDs on the substrate; transferring the micro LEDs to a transient substrate, where the micro LEDs are bonded to the transient substrate through an adhesive layer; forming a support assembly by etching the adhesive layer, where the support assembly is in a mesh shape and surrounds the micro LEDs; and transferring, with a transfer structure, the micro LEDs to a display substrate.

In some implementations, the transfer structure is an elastomeric stamp, and the elastomeric stamp is made of polydimethylsiloxane (PDMS).

In some implementations, forming the micro LEDs includes: forming a first semiconductor layer on the substrate; forming a light-emitting layer on the first semiconductor layer; forming a second semiconductor layer on the light-emitting layer; forming a transparent conductive layer on the second semiconductor layer; depositing a first electrode on the first semiconductor layer; and depositing a second electrode on the second semiconductor layer.

In some implementations, forming the micro LEDs further includes: depositing a reflective layer on the second semiconductor layer and the transparent conductive layer.

In some implementations, forming the micro LEDs further includes: forming a first conductive channel and a second conductive channel in the reflective layer, where the first conductive channel is in contact with the first semiconductor layer, and the second conductive channel is in contact with the transparent conductive layer.

In some implementations, forming the first conductive channel and the second conductive channel in the reflective layer includes: depositing a photoresist layer on the reflective layer; defining two openings on the photoresist layer; and forming the first conductive channel and the second conductive channel by etching the reflective layer with the photoresist layer as a mask, where an angle between a side wall of each of the two openings and the reflective layer is greater than 90 degrees.

In some implementations, a silicon content of the adhesive layer ranges from 20% to 85%.

In some implementations, the support assembly includes a first support structure, and forming the support assembly by etching the adhesive layer includes: forming the first support structure of the support assembly by dry etching the adhesive layer with an etching gas, where the etching gas is oxygen or chlorine.

In some implementations, the support assembly further includes a second support structure, and the method for manufacturing the micro LED display further includes: forming an oxide layer on the transient substrate; and forming the second support structure by etching the oxide layer, where the second support structure has a radial size smaller than a distance between two electrodes of the micro LED, and has a height greater than a height of the electrodes.

In view of the above deficiencies of the related art, the disclosure provides a method for manufacturing a weakened structure and a method for manufacturing a micro LED display, which aims to solve the problem that etching of an adhesive between a substrate and a micro LED cannot be controlled precisely.

In order to solve the above technical problem, the disclosure is achieved through the following technical solutions.

The disclosure provides a method for manufacturing a weakened structure. The weakened structure includes a first support structure. A method for manufacturing the first support structure includes: forming an adhesive layer on a micro LED and/or a transient substrate; transferring the micro LED to the transient substrate, where the micro LED is bonded to the transient substrate through the adhesive layer; and forming the first support structure by etching the adhesive layer, where the first support structure is in a mesh shape and surrounds the micro LED.

According to the above method for manufacturing the weakened structure, the adhesive layer can be etched to have a mesh shape, in this situation, an etching process of the adhesive is easy to control while the adhesive layer can support the micro LED, and therefore, yield of mass transfer can be improved.

Optionally, the adhesive layer is made of organic silicide.

Optionally, a silicon content of the adhesive layer ranges from 20% to 85%, which can ensure that the first support structure formed after etching has a mesh structure, and ensure that the first support structure formed has an appropriate mesh density, to avoid a situation where the first support structure cannot support the micro LED due to too low silicon content, and avoid a situation where a transfer structure cannot pick up the micro LED caused by excessive adhesion force between the first support structure and the micro LED due to excessive silicon content.

Optionally, the adhesive layer is made of materials containing groups of carbon, hydrogen, and nitrogen.

Optionally, forming the first support structure includes: dry etching the adhesive layer, with an etching gas being oxygen or chlorine.

Optionally, the first support structure is made of silicon oxide.

The adhesive layer and the first support structure are designed to be made of the above materials, which can ensure that only the solid and mesh-like first support structure exists after the etching is completed, while substances in the adhesive layer other than substances for forming the first support structure react with the etching gas to generate substances that are easy to remove.

Optionally, the weakened structure further includes a second support structure. The second support structure is located between two electrodes of the micro LED when the micro LED is bonded to the transient substrate.

The above second support structure further supports the micro LED, which can ensure stability of the micro LED.

Optionally, forming the second support structure includes: forming an oxide layer on the transient substrate; and forming the second support structure by etching the oxide layer, where the second support structure has a radial size smaller than a distance between the two electrodes of the micro LED.

Optionally, the second support structure is made of silicon oxide.

Optionally, the second support structure is spaced apart from the micro LED by a preset distance when the micro LED is bonded to the transient substrate, which can ensure that there is no adhesion force between the second support structure and the micro LED, thereby ensuring yield of mass transfer.

Based on the same inventive concept, the disclosure further provides a method for manufacturing a micro LED display. The method for manufacturing the micro LED display includes: providing a substrate; forming a plurality of micro LEDs on the substrate; transferring the micro LEDs to a transient substrate, where the micro LEDs are bonded to the transient substrate through an adhesive layer; forming a first support structure by etching the adhesive layer, where the first support structure is in a mesh shape and surrounds the micro LEDs; and transferring the micro LEDs to a display substrate.

According to the above method for manufacturing the micro LED display, the adhesive layer can be etched to have a mesh shape, in this situation, an etching process of the adhesive is easy to control while the adhesive layer can support the micro LEDs, and therefore, yield of mass transfer can be improved.

Optionally, a transfer structure is an elastomeric stamp, and the elastomeric stamp is made of PDMS.

Optionally, forming the micro LEDs includes: forming a first semiconductor layer on the substrate; forming a light-emitting layer on the first semiconductor layer; forming a second semiconductor layer on the light-emitting layer; forming a transparent conductive layer on the second semiconductor layer; depositing a first electrode on the first semiconductor layer; and depositing a second electrode on the second semiconductor layer.

Optionally, forming the micro LEDs further includes: depositing a reflective layer on the second semiconductor layer and the transparent conductive layer.

Optionally, forming the micro LEDs further includes: forming a first conductive channel and a second conductive channel in the reflective layer, where the first conductive channel is in contact with the first semiconductor layer, and the second conductive channel is in contact with the transparent conductive layer.

Optionally, forming the first conductive channel and the second conductive channel includes: depositing a photoresist layer on the reflective layer; defining openings on the photoresist layer; and etching the reflective layer with the photoresist layer as a mask, where an angle between a side wall of the opening and the reflective layer is greater than 90 degrees.

In the above process, the electrodes formed can be ensured to have a large radial size, thereby facilitating welding.

Any product implementing the disclosure does not necessarily have to achieve all the above-mentioned advantages at the same time.

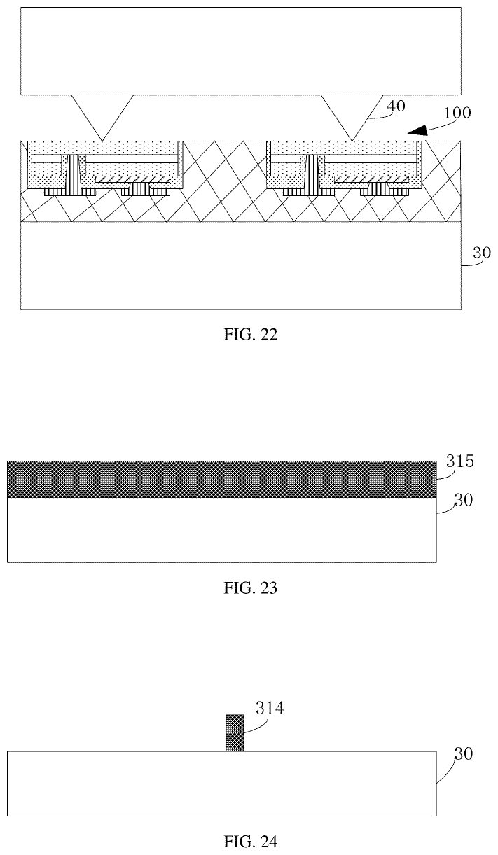

Referring to FIG. 22 and FIG. 30, a micro LED display includes a display substrate 50 and multiple micro LEDs 100 arranged on the display substrate 50. The display substrate 50 is provided with a driving circuit for driving the micro LEDs 100 to work. The multiple micro LEDs 100 are electrically connected to the driving circuit, and the multiple micro LEDs 100 are arranged in a matrix on the display substrate 50 to form a display region of the micro LED display. Micro LED displays have advantages of long service life, high contrast, high resolution, fast response, wide viewing angle, rich colors, ultra-high brightness, and low power consumption, and can be used in televisions, laptops, monitors, mobile phones, watches, wearable displays, vehicle-mounted devices, virtual reality (VR) devices, augmented reality (AR) devices, portable electronic devices, game consoles, or other electronic devices.

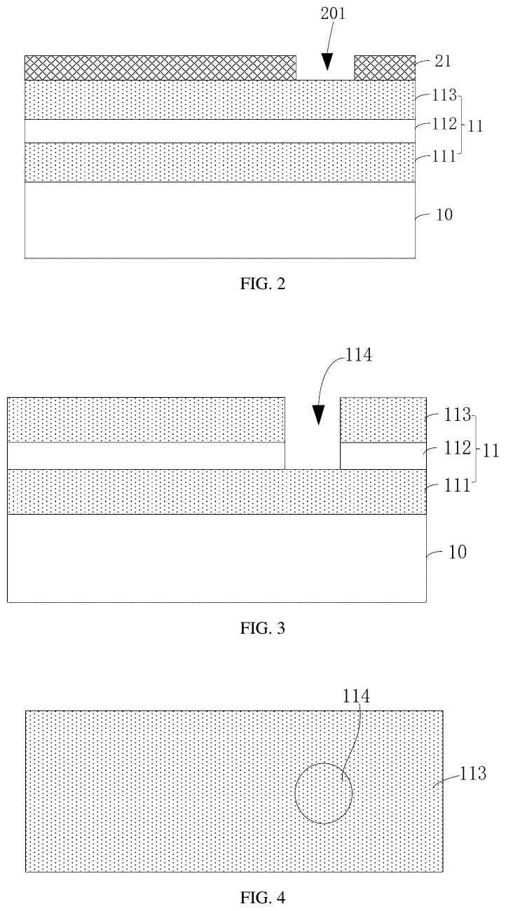

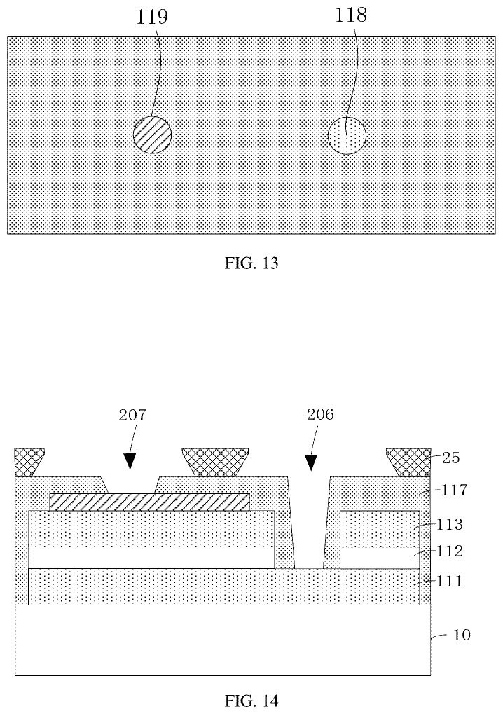

Referring to FIG. 2 to FIG. 22, during manufacturing of the micro LED display, multiple micro LEDs 100 can be formed on a substrate 10, for example, a semiconductor epitaxial layer 11 is deposited on the substrate 10, and the micro LED 100 is formed after processes such as exposure, development, etching, and metal deposition. According to the type of the micro LED 100, different materials can be used for the substrate. For example, the micro LED 100 that emits ultraviolet light can be made of gallium nitride (GaN), and accordingly, the substrate 10 of such micro LED 100 is typically a heterogeneous epitaxy on sapphire, or a self-supporting gallium nitride substrate made using hydride vapor phase epitaxy or ammonothermal method. For other colors of micro LEDs 100, a gallium arsenide (GaAs) substrate, a gallium phosphide (GaP) substrate, or substrates made of other materials can be used. Multiple micro LEDs 100 are arranged on a same substrate 10 to form an array of the micro LEDs 100. After sorting and selecting, micro LEDs 100 are transferred to a transient substrate 30 as required, finally, the micro LEDs 100 are transferred to a display substrate 50. Or the micro LEDs 100 on the substrate 10 are directly transferred to the display substrate 50 as required, so as to form the micro LED display. The micro LED 100 is small in size, for example, the number of micro LEDs 100 on a 4-inch wafer is 14×10⁶, and the number of micro LEDs required to form a micro LED display is also very large. Specifically, micro LEDs 100 can be efficiently transferred to the display substrate 50 through mass transfer.

Referring to FIG. 21 and FIG. 22, the mass transfer herein specifically includes electrostatic force transfer, van der Waals force transfer, magnetic force transfer, laser selective transfer, fluid transfer, direct transfer printing, and other transfer methods. In an implementation of the disclosure, the mass transfer includes, for example, electrostatic force transfer, van der Waals force transfer, magnetic force transfer, and other transfer methods. When performing mass transfer, a transfer structure 40 is used to pick up micro LEDs 100 and transfer these LEDs to the display substrate 50. Since the micro LEDs 100 are bonded to the transient substrate 30 or the substrate 10 through an adhesive, a part of the adhesive needs to be etched off before picking up the micro LEDs 100 with the transfer structure 40, and a remaining part of the adhesive is left to support the micro LEDs 100. However, a width of the remaining adhesive is difficult to control. If the width of the remaining adhesive is too small, the micro LED(s) 100 may fall, which is prone to cause damage of the micro LED(s) 100. If the width of the remaining adhesive is too large, an adhesion force between the micro LED 100 and the adhesive is relatively large, so that the transfer structure cannot pick up all the selected micro LEDs 100, resulting in low yield.

In view of the above, the disclosure provides a method for manufacturing a weakened structure and a method for manufacturing a micro LED display. It is to be noted that, the weakened structure of the disclosure refers to a support assembly. In some implementations, the weakened structure includes a mesh-like first support structure. In other implementations, the support assembly includes a mesh-like first support structure and a second support structure. Such a weakened structure has weakened support and a weakened adhesion force, which can provide an appropriate adhesion force for the micro LED to facilitate pickup of the micro LED, while providing sufficient support for the micro LED. The adhesive is doped with substances that do not react with an etching gas, and organic substances in the adhesive are etched to form a mesh-like first support structure. The first support structure formed can support the micro LEDs, and an etching process of the adhesive is easy to control, which can improve yield of mass transfer.

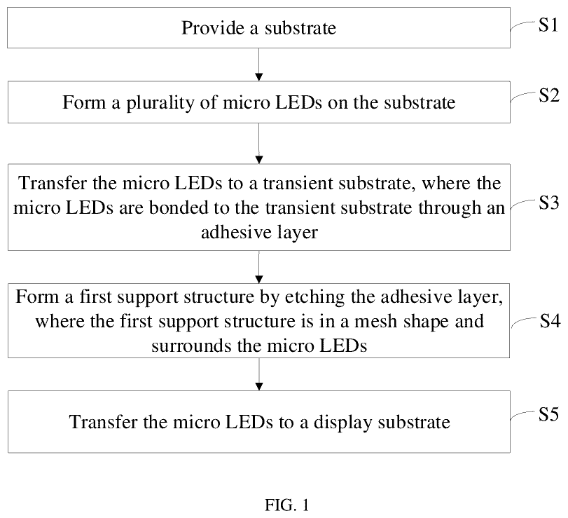

Referring to FIG. 1, a method for manufacturing a micro LED display provided in the disclosure includes the following.

S1, provide a substrate.

S2, form multiple micro LEDs on the substrate.

S3, transfer the micro LEDs to a transient substrate, where the micro LEDs are bonded to the transient substrate through an adhesive layer.

S4, form a first support structure by etching the adhesive layer, where the first support structure is in a mesh shape and surrounds the micro LEDs.

S5, transfer the micro LEDs to a display substrate.

Referring to FIG. 1 and FIG. 2, in an implementation of the disclosure, the substrate 10 includes a semiconductor structure made of silicon, silicon germanium, silicon carbide, sapphire, indium phosphide, gallium arsenide, indium arsenide, or other III/V compounds, and also includes a stacked structure composed of these semiconductors, or may be silicon on insulator, stacked silicon on insulator, stacked silicon germanium on insulator, silicon germanium on insulator, germanium on insulator, etc. The material of the substrate 10 can be determined according to the type of the micro LED 100 to-be-formed and a semiconductor epitaxial layer 11 of the substrate 10. In some implementations, the micro LED 100 is a micro LED 100 that emits blue light or green light, and the material of the semiconductor epitaxial layer 11 is, for example, gallium nitride (GaN) or indium gallium nitride (InGaN), in this case, the material of the substrate 10 is, for example, sapphire (Al₂O₃), silicon carbide (SiC), zinc oxide (ZnO), gallium nitride (GaN), aluminum nitride (AlN), and silicon (Si). In other implementations, the micro LED 100 is a micro LED 100 that emits red light or yellow light, and the material of the semiconductor epitaxial layer 11 is, for example, one or more of gallium phosphide (GaP), aluminum gallium arsenide (AlGaAs), or aluminum gallium indium phosphorus (AlGaInP), in this case, the material of the substrate 10 is, for example, gallium phosphide (GaP) or gallium arsenide (GaAs).

Multiple micro LEDs of the same type may be formed on the substrate 10 at the same time. In the disclosure, referring to FIG. 2, a single micro LED is taken as an example to illustrate forming of the micro LED. In an implementation of the disclosure, forming the micro LED includes growing a semiconductor epitaxial layer 11 on a substrate 10. The semiconductor epitaxial layer 11 includes a first semiconductor layer 111, a light-emitting layer 112, and a second semiconductor layer 113 which are grown sequentially, that is, the light-emitting layer 112 is disposed on the first semiconductor layer 111, and the second semiconductor layer 113 is disposed on the light-emitting layer 112. In this implementation, the first semiconductor layer 111 may be an N-type semiconductor layer doped with a first impurity, and accordingly, the second semiconductor layer 113 may be a P-type semiconductor layer doped with a second impurity; alternatively, the first semiconductor layer 111 may be a P-type semiconductor layer doped with a second impurity, and accordingly, the second semiconductor layer 113 may be an N-type semiconductor layer doped with a first impurity. The first impurity is, for example, a donor impurity, and the second impurity is, for example, an acceptor impurity. According to the semiconductor material used, the element of the first impurity may be different from the element of the second impurity. In this implementation, the first semiconductor layer 111 and the second semiconductor layer 113 can be made of gallium nitride, that is, the first semiconductor layer 111 is an N-type gallium nitride layer and the second semiconductor layer 113 is a P-type gallium nitride layer, in this case, the element of the first impurity can be silicon (Si) or tellurium (Te), and the element of the second impurity can be magnesium (Mg) or zinc (Zn). In other implementations, the first semiconductor layer 111 and the second semiconductor layer 113 may also be made of other suitable materials.

Referring to FIG. 2 again, in an implementation of the disclosure, the light-emitting layer 112 is an intrinsic semiconductor layer or a low-doped semiconductor layer. The light-emitting layer 112 has a doping concentration lower than an adjacent semiconductor layer of the same doping type, and the light-emitting layer 112 may be a quantum well light-emitting layer. In this implementation, the semiconductor epitaxial layer 11, for example, emits blue light or green light, and the light-emitting layer 112 is made of indium gallium nitride (InGaN). In other implementations, the light-emitting layer 112 may be, for example, a quantum well that emits light in different wavelength bands. The light-emitting layer 112 may be made of one or more of materials such as zinc selenide (ZnSe), indium gallium nitride/gallium nitride (InGaN/GaN), indium gallium nitride/gallium nitride (InGaN/GaN), gallium phosphide (GaP), aluminum gallium phosphide (AlGaP), or aluminum gallium arsenide (AlGaAs).

Referring to FIG. 2 to FIG. 4 again, in an implementation of the disclosure, after the semiconductor epitaxial layer 11 is formed, the semiconductor epitaxial layer 11 is etched to form a MESA structure. For example, a recess 114 is defined in the semiconductor epitaxial layer 11. The bottom of the recess 114 is in contact with the first semiconductor layer 111, and is spaced apart from the substrate 10 by a preset distance. In this implementation, a patterned first photoresist layer 21 can be formed on the second semiconductor layer 113, where the first photoresist layer 21 covers the second semiconductor layer 113 in this step, and the first photoresist layer 21 defines a first opening 201 which is used to define the position of the recess 114. In this implementation, the first opening 201 is circular in shape. In other implementations, the first opening 201 may be rectangle, polygon, or in other shapes. After the first photoresist layer 21 is formed, the first photoresist layer 21 is used as a mask to dry-etch the second semiconductor layer 113, the light-emitting layer 112, and part of the first semiconductor layer 111, so as to form the recess 114, and the etching gas is, for example, boron trioxide (BCl₃) or chlorine (Cl₂). After the recess 114 is formed, the first photoresist layer 21 is removed.

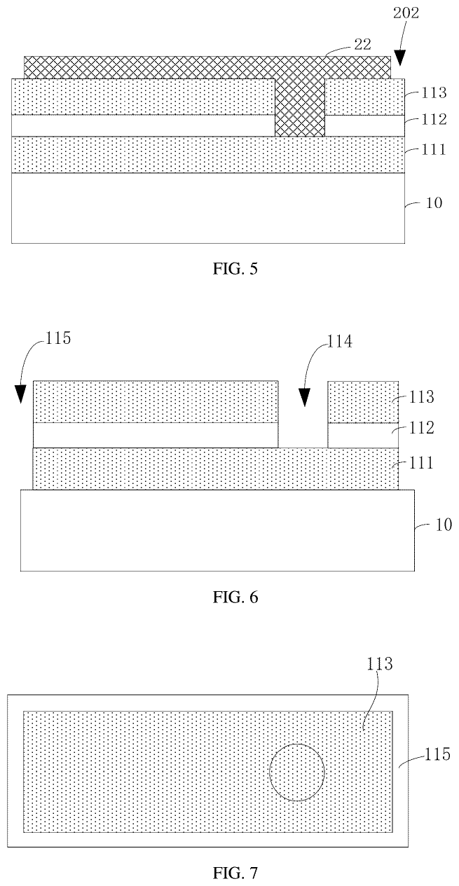

Referring to FIG. 6, in an implementation of the disclosure, after the recess 114 is formed and the first photoresist layer 21 is removed, a groove 115 is formed on the outer side of the micro LED. The groove 115 is in contact with the substrate 10, and the groove 115 surrounds each micro LED to isolate adjacent micro LEDs. Specifically, referring to FIG. 5 to FIG. 7, a patterned second photoresist layer 22 is formed on the second semiconductor layer 113, and multiple second openings 202 are defined in the second photoresist layer 22 to define the position of the groove 115. The second opening 202 surrounds the micro LED 100, and the second opening 202 is, for example, a rectangular ring in shape. After the second photoresist layer 22 is formed, the second photoresist layer 22 is used as a mask to dry-etch the semiconductor epitaxial layer 11 to the substrate 10 to form the groove 115, and an etching depth is, for example, 4 um˜8 um. After the groove 115 is formed, the second photoresist layer 22 is removed.

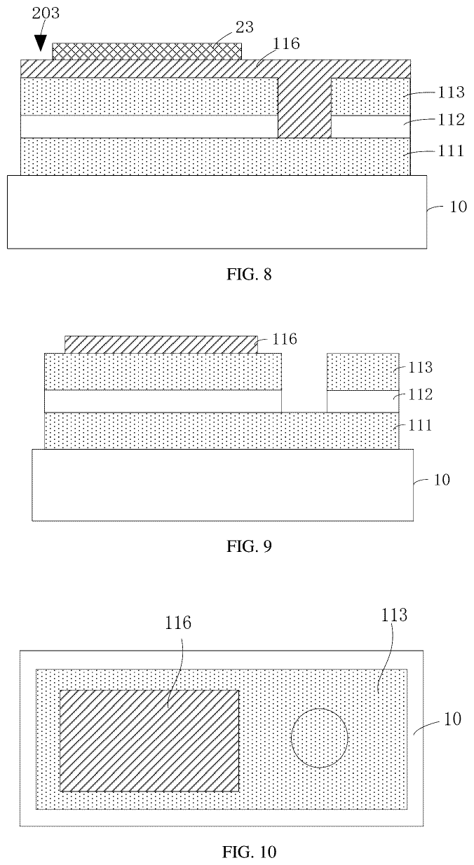

Referring to FIG. 9, in an implementation of the disclosure, after the groove 115 is formed and the second photoresist layer 22 is removed, a transparent conductive layer 116 is formed on the second semiconductor layer 113, and the transparent conductive layer 116 is located on one side of the recess 114. Specifically, referring to FIG. 8 to FIG. 10, a layer of indium tin oxide (ITO) is sputtered on the second semiconductor layer 113, and the thickness of the ITO is, for example, 200 angstroms to 2000 angstroms. A patterned third photoresist layer 23 is formed on the ITO, and a third opening 203 is defined in the third photoresist layer 23 to define the position of the transparent conductive layer 116. In this implementation, the third opening 203 is located on one side of a convex portion and is rectangular in shape. After the third photoresist layer 23 is formed, the ITO is wet-etched with the third photoresist layer 23 as a mask to form the transparent conductive layer 116, and then the third photoresist layer 23 is removed.

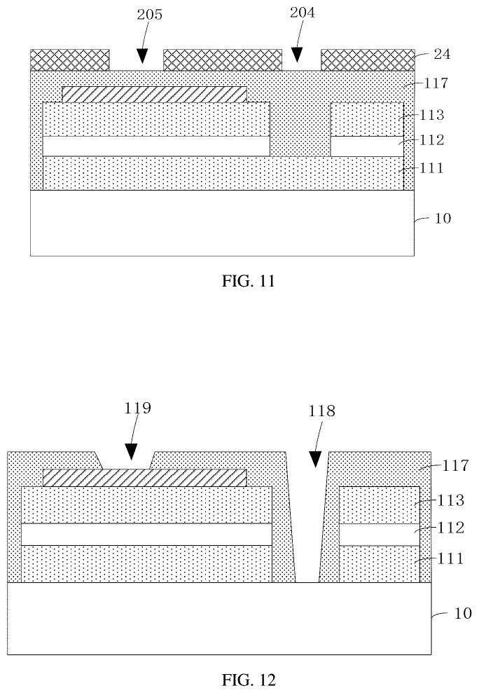

Referring to FIG. 12, in an implementation of the disclosure, after the third photoresist layer 23 is removed, a reflective layer 117 is formed on the transparent conductive layer 116. The reflective layer 117 covers the transparent conductive layer 116, the second semiconductor layer 113, the recess 114, and the groove 115. The reflective layer 117 defines a first conductive channel 118 and a second conductive channel 119. The first conductive channel 118 communicates with the semiconductor layer 111, and the second conductive channel 119 communicates with the transparent conductive layer 116. The reflective layer 117 includes, for example, a silicon oxide layer and a silicon nitride layer. Specifically, referring to FIG. 11 to FIG. 13, for example, stacked layers of silicon oxide and silicon nitride are evaporated on the transparent conductive layer 116, the second semiconductor layer 113, the recess 114, and the groove 115 to form the reflective layer 117, and the thickness of the reflective layer 117 is, for example, 1 um˜4 um. The reflective layer 117 can reflect the light emitted by the light-emitting layer 112, so that the light emitted by the micro LED 100 is exited from one side of the first semiconductor layer 111. After the reflective layer 117 is formed, a patterned fourth photoresist layer 24 is formed on the reflective layer 117. A fourth opening 204 and a fifth opening 205 are defined in the fourth photoresist layer 24. The fourth opening 204 is located above the recess 114 to define the position of the first conductive channel 118. The fifth opening 205 is located above the transparent conductive layer 116 to define the position of the second conductive channel 119. After the fourth photoresist layer 24 is formed, the fourth photoresist layer 24 is used as a mask to etch the reflective layer 117, to form the first conductive channel 118 which is in the recess 114 and in communication with the first semiconductor layer 111, and to form the second conductive channel 119 which is above the transparent conductive layer 116 and in communication with the transparent conductive layer 116. The first conductive channel 118 and the second conductive channel 119 may be in any shape, such as a cylinder, a quadrangular prism, or columns of other shapes. In this implementation, for example, dry etching is used, and the etching gas is one or more of tetrafluoromethane (CF₄), oxygen (O₂), or argon (Ar). After the first conductive channel 118 and the second conductive channel 119 are formed, the fourth photoresist layer 24 can be removed.

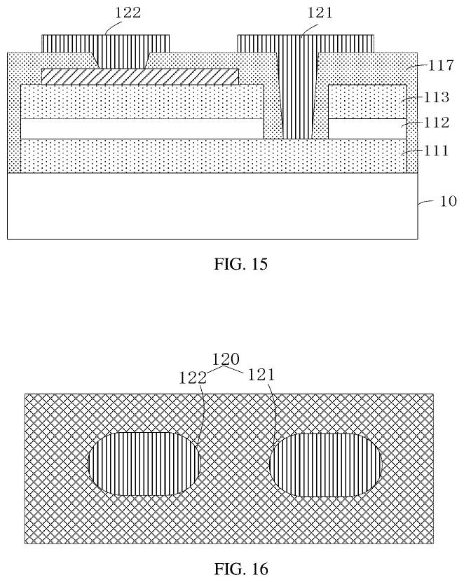

Referring to FIG. 15, in an implementation of the disclosure, after the reflective layer 117 is formed, a first electrode 121 is formed in the first conductive channel 118, and a second electrode 122 is formed in the second conductive channel 119. Specifically, referring to FIG. 14 to FIG. 16, in this implementation, a patterned fifth photoresist layer 25 is first formed on the reflective layer 117, and the fifth photoresist layer 25 defines a sixth opening 206 and a seventh opening 207. The sixth opening 206 defines the position of the first electrode 121, and the seventh opening 207 defines the position of the second electrode 122. In some implementations, the fourth photoresist layer 24 is not removed before forming electrodes 120, and the first electrode 121 and the second electrode 122 are formed with the fourth photoresist layer 24 as a mask. In this implementation, the fifth photoresist layer 25 is used as a mask to form the first electrode 121 and the second electrode 122. The sixth opening 206 exposes the first conductive channel 118 and has a diameter larger than the first conductive channel 118, the seventh opening 207 exposes the second conductive channel 119 and has a diameter larger than the second conductive channel 119, so as to form the electrodes 120 with a relatively large area. After the patterned photoresist layer is formed, the first electrode 121 is formed by evaporating metal in the first conductive channel 118 and the sixth opening 206, and the second electrode 122 is formed by evaporating metal in the second conductive channel 119 and the seventh opening 207. The thickness of the first electrode 121 is 1 um˜4 um, and the thickness of the second electrode 122 is 1 um˜4 um. The first electrode 121 and the second electrode 122 each are made of gold (Au) alloy for example. For example, the first electrode 121 is an N-type electrode 120 and made of Ni/Au, and the second electrode 122 is a P-type electrode 120 and made of Ni/Al/Ni/Au.

Referring to FIG. 2 to FIG. 14, in this implementation, forming the patterned photoresist layer includes: coating photoresist, and then removing a part of the photoresist at the position where an opening(s) is needed through a wet method with alkaline solution or a dry method (ashing), to pattern the coated photoresist to form the patterned photoresist layer. The photoresist layer may be made of positive photoresist or negative photoresist. The fifth photoresist layer 25 is, for example, made of negative photoresist, after the photoresist in a non-exposed region of the fifth photoresist layer 25 is dissolved in the developer, an angle between a side surface of the patterned photoresist layer thus formed and the reflective layer 117 is less than 90 degrees, which ensures that the fifth photoresist layer 25 does not affect deposition of the electrodes 120, that is, an angle between the reflective layer 117 and side walls of the sixth opening 206 and the seventh opening 207 is greater than 90 degrees.

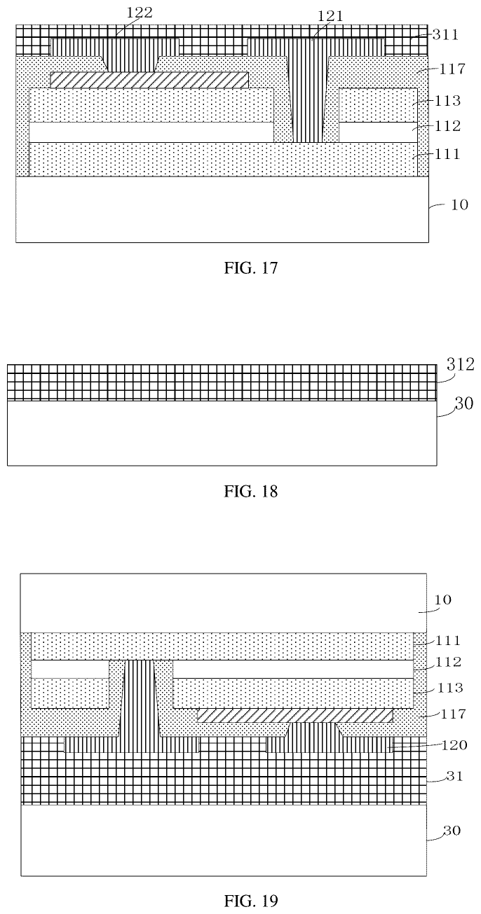

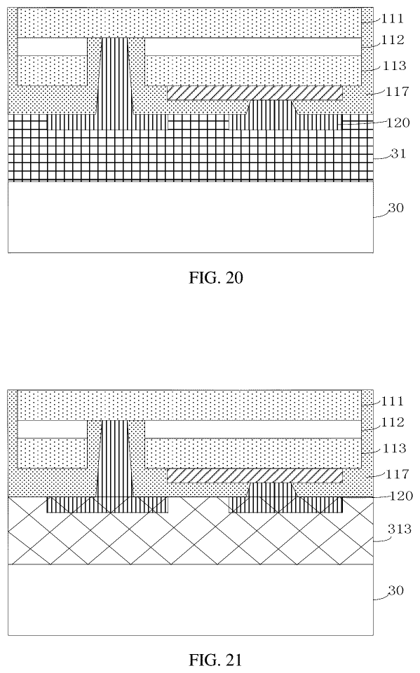

Referring to FIG. 17 to FIG. 19, in an implementation of the disclosure, after the micro LED is formed, the micro LED 100 is transferred to a transient substrate 30. Specifically, a layer of an adhesive layer 31 is coated on the micro LED 100 and/or the transient substrate 30, and then the micro LED 100 and the transient substrate 30 are bonded through a binding machine, where the micro LED 100 and the transient substrate 30 are bonded together via the adhesive layer 31. The transient substrate 30 is, for example, a sapphire substrate. As illustrated in FIG. 20, after the micro LED 100 is transferred to the transient substrate 30, the substrate 10 is removed. As an example, the substrate 10 is peeled off through laser lift off (LLO) technology.

Referring to FIG. 17 to FIG. 19, in this implementation, the adhesive layer 31 includes a first adhesive layer 311 and a second adhesive layer 312. The first adhesive layer 311 is disposed on the micro LED 100, and the first adhesive layer 311 covers the first electrode 121, the second electrode 122, and a gap between adjacent micro LEDs 100. The second adhesive layer 312 is disposed on the transient substrate 30. When the micro LED 100 and the transient substrate 30 are bonded through the bonding machine, the first adhesive layer 311 and the second adhesive layer 312 are fused to form the adhesive layer 31. During bonding, the adhesive is heated to fuse the first adhesive layer 311 and the second adhesive layer 312.

Referring to FIG. 17 to FIG. 19, in this implementation, the adhesive layer 31 is, for example, made of an organic silicon compound, and a silicon content of the adhesive layer 31 is, for example, 20% to 85%, to ensure that a mesh-like scaffold can be formed after etching the adhesive layer 31, that is, a first support structure 313 of the weakened structure can be formed. Moreover, silicon ranging from 20% to 85% in the adhesive layer 31 can ensure that the first support structure 313 formed has an appropriate mesh density, to avoid a situation where the first support structure 313 cannot support the micro LED 100 due to too low silicon content, and avoid a situation where a transfer structure cannot pick up the micro LED 100 caused by excessive adhesion force between the first support structure 313 and the micro LED 100 due to excessive silicon content. The adhesive layer 31 also contains groups of carbon, hydrogen, and nitrogen, and these groups can react with the etching gas during etching to generate easily removable substances.

Referring to FIG. 19 to FIG. 22, in an implementation of the disclosure, after the substrate 10 is removed, the adhesive layer 31 is etched, and the groups of carbon, hydrogen, and nitrogen contained in the adhesive layer 31 are etched off, while the mesh-like first support structure 313 is left. Specifically, the adhesive layer can be dry-etched, and the etching gas is, for example, oxygen or chlorine. During etching, oxygen (or chlorine) reacts with the groups of carbon, hydrogen, and oxygen contained in the adhesive layer 31, so that the carbon, hydrogen, and nitrogen in the adhesive layer 31 form compounds with oxygen. For example, the etching gas is oxygen, the substances generated from the groups of carbon, hydrogen, and oxygen are carbon dioxide, water, and nitrogen dioxide, where carbon dioxide and nitrogen dioxide are gases, and water is liquid, which can be removed directly. The silicon in the adhesive layer 31 reacts with oxygen to generate silicon oxide, to form the mesh-like first support structure 313. The first support structure 313 formed surrounds the micro LED 100, which not only supports the micro LED 100, but also ensures that the micro LED 100 does not shake.

Referring to FIG. 22 and FIG. 30, in an implementation of the disclosure, after the first support structure 313 is formed, a transfer structure 40 is used to transfer the micro LED 100 to a display substrate 50 to form a micro LED display.

Referring to FIG. 28, in another implementation of the disclosure, the weakened structure further includes a second support structure 314, and the second support structure 314 is disposed on the transient substrate 30. Specifically, as illustrated in FIG. 23 to FIG. 28, a layer of silicon oxide is deposited on the transient substrate 30 to form a support layer 315. A patterned photoresist layer is formed on the support layer, and the photoresist layer defines an opening to define the position of the second support structure 314. After the patterned photoresist layer is formed, the support layer 315 is etched with the patterned photoresist layer as a mask to form the second support structure 314. For example, the support layer 315 is etched through wet etching.

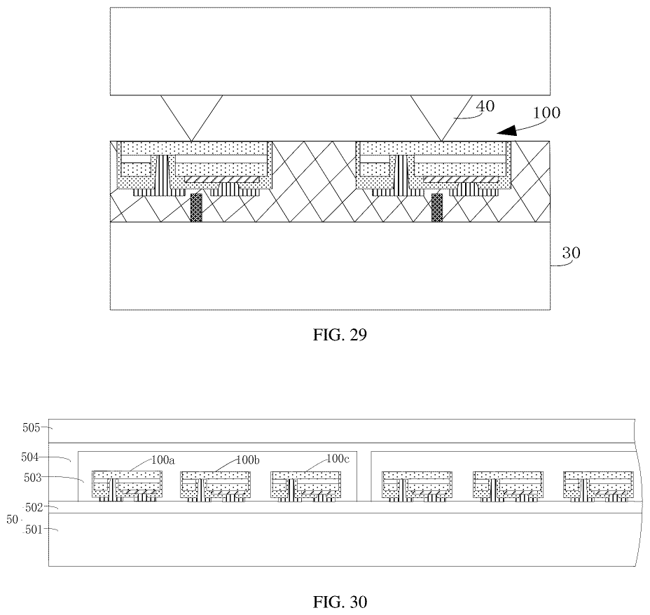

Referring to FIG. 28 and FIG. 29, in this implementation, the transient substrate may be provided with multiple second support structures 314, the second support structures 314 are in one-to-one correspondence with the micro LEDs 100 in terms of position, and a radial size of the second support structure 314 is smaller than a distance between the first electrode 121 and the second electrode 122. When the micro LED 100 is bonded to the transient substrate 30, the second support structure 314 is located between the first electrode 121 and the second electrode 122 of the micro LED.

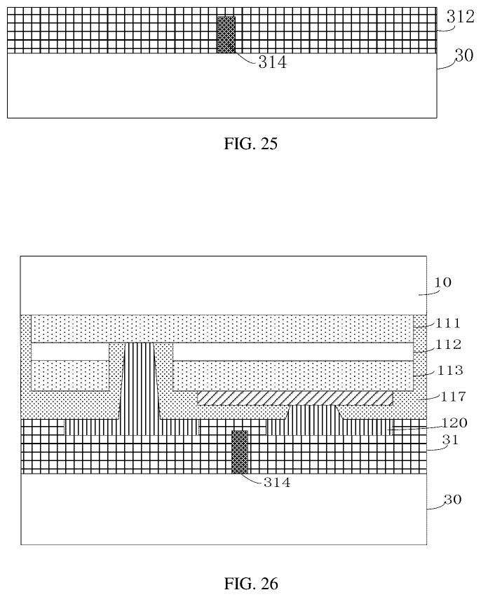

Referring to FIG. 17 and FIG. 25, in another implementation of the disclosure, after the second support structure 314 is formed, a first adhesive layer 311 is formed on the micro LED and covers the first the electrode 121, the second electrode 122, and a gap between adjacent micro LEDs 100, and a second adhesive layer 312 is formed on the transient substrate 30 and covers the second support structure 314 and a gap between adjacent second support structures 314. As illustrated in FIG. 26, when the micro LED 100 and the transient substrate 30 are bonded through the bonding machine, the first adhesive layer 311 and the second adhesive layer 312 are fused to form the adhesive layer 31.

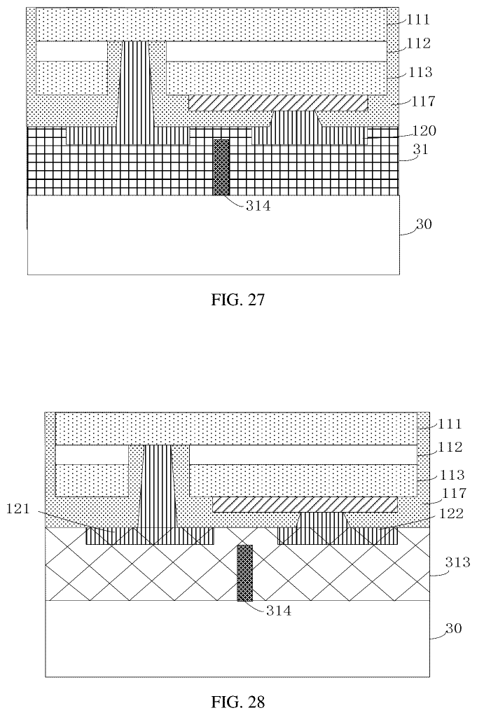

Referring to FIG. 26 and FIG. 27, in another implementation of the disclosure, after the micro LED 100 is transferred to the transient substrate 30, the substrate 10 is peeled off through, for example, LLO technology. After the substrate 10 is removed, the adhesive layer 31 is etched, where the groups of carbon, hydrogen, and nitrogen contained in the adhesive layer 31 are etched off, while the mesh-like first support structure 313 and the second support structure 314 are left. Specifically, the adhesive layer can be dry-etched, and the etching gas is, for example, oxygen or chlorine. During etching, oxygen (or chlorine) reacts with the groups of carbon, hydrogen, and oxygen contained in the adhesive layer 31, so that the carbon, hydrogen, and nitrogen in the adhesive layer 31 form compounds with oxygen. For example, the etching gas is oxygen, the substances generated from the groups of carbon, hydrogen, and oxygen are carbon dioxide, water, and nitrogen dioxide, where carbon dioxide and nitrogen dioxide are gases and water is liquid and therefore can be removed directly. The silicon in the adhesive layer 31 reacts with oxygen to generate silicon oxide, to form the mesh-like first support structure 313. The first support structure 313 formed surrounds the micro LED 100, which not only supports the micro LED 100, but also ensures that the micro LED 100 does not shake. The second support structure 314 is located between the first electrode 121 and the second electrode 122, and the height of the second support structure 314 is greater than the height of the electrodes. When the first adhesive layer 311 and the second adhesive layer 312 are fused, the second support structure 314 is spaced apart from the micro LED 100 by a preset distance, to ensure that there is no adhesion force between the second support structure 314 and the micro LED 100 during mass transfer.

Referring to FIG. 29 and FIG. 30, in an implementation of the disclosure, after the first support structure 313 and the second support structure 314 are formed, the micro LED 100 is transferred to the display substrate 50 with the transfer structure 40 to form a micro LED display.

Referring to FIG. 22 and FIG. 29, the micro LED 100 can be transferred in many methods. According to a force involved in the transfer process or a specific transfer manner, the method for transferring the micro LED 100 may be based on van der Waals force, electrostatic force, magnetic force, laser transfer printing, fluid self-assembly, roll-to-roll transfer printing, or the like. In this implementation, the micro LED 100 is transferred through the van der Waals force, the transfer structure 40 is, for example, an elastomeric stamp, and the elastomeric stamp is, for example, made of PDMS. The micro LED 100 can be picked up with the elastomeric stamp and transferred to the display substrate 50. In a process of picking up the micro LED 100, the elastomeric stamp maintains a high speed, and at this time, an adsorption force between the elastomeric stamp and the (LED) device is relatively large. In a process of placing the micro LED 100 onto the display substrate 50, the elastomeric stamp maintains a low transfer speed, and at this time, the adsorption force between the elastomeric stamp and the device is relatively small. When transferring the micro LED 100 with the elastomeric stamp, the temperature of the elastomeric stamp can be adjusted to ensure a transfer effect. As an example, in a process of picking up and transferring the micro LED 100, a low temperature can ensure a relatively large adsorption force between the elastomeric stamp and the device. In a process of placing the micro LED 100, a high temperature can ensure a relatively small adsorption force between the elastomeric stamp and the device.

Referring to FIG. 22 and FIG. 29, in other implementations, the micro LED 100 can be transferred through electrostatic force or magnetic force. If the micro LED 100 is transferred through electrostatic force, the transfer structure 40 is, for example, an electrostatic transfer head, where two separate electrodes are disposed at the top of the electrostatic transfer head, the two electrodes are led out via metal, and an insulating material is deposited on the metal electrodes. When alternating current is applied to the two electrodes, the micro LED 100 will be adsorbed to the electrostatic transfer head under the action of Coulomb force, so as to transfer the micro LED 100 to the display substrate 50. If the micro LED 100 is transferred through magnetic force, the transfer structure 40 is, for example, a micromagnetic transfer head, where the micromagnetic transfer head has an iron core made of a magnetic material such as ferrosilicon alloy (FeSi), and a coil made of a gold wire in a plane or a multi-layer plane. When current flows through the coil, a strong magnetic field is generated in the coil to pick up the micro LED 100.

Referring to FIG. 30, in an implementation of the disclosure, the micro LED display includes a display substrate 50 and multiple micro LEDs 100 disposed on the display substrate 50. For example, the display substrate 50 is a thin-film transistor (TFT) array substrate, and includes a base substrate 501 and a circuit layer 502 disposed on the base substrate 501. The circuit layer 502 includes multiple TFTs for driving the micro LEDs 100. In this implementation, for example, the display substrate 50 is provided with multiple red micro LEDs 100a, green micro LEDs 100b, and blue micro LEDs 100c. Each of these micro LEDs 100 serves as a sub-pixel, where the red micro LED 100a forms a red sub-pixel, the green micro LED 100b forms a green sub-pixel, and the blue micro LED 100c forms a blue sub-pixel. The red micro LED 100a, the green micro LED 100b, and the blue micro LED 100c which are arranged in order form a pixel.

Referring to FIG. 30, in an implementation of the disclosure, within a pixel, a planarization layer 503 is formed on the (three) micro LEDs 100 and between adjacent micro LEDs 100 through exposure and development processes. A protective layer 504 may also be disposed on the planarization layer 503. The protective layer 504 is disposed between adjacent pixels and above the pixels. A protective substrate 505 may also be disposed on the protective layer 504. The protective substrate 505 and the protective layer 504 bonded to the protective substrate 505 form a sealed cavity to protect the micro LED 100 inside.

In sum, according to the method for manufacturing the weakened structure and the method for manufacturing the micro LED display provided in the disclosure, micro LEDs are formed on the substrate, the micro LEDs are bonded to the transient substrate through the adhesive layer, and the adhesive layer is etched to form the mesh-like first support structure, to support the micro LED and ensure that the micro LED does not shake. Then, the micro LED is transferred to the display substrate with the transfer structure to form the micro LED display. In the method for manufacturing the weakened structure and the method for manufacturing the micro LED display provided in the disclosure, the adhesive layer is etched into the mesh-like first support structure, the manufacturing process is simple and easy to operate, which can improve the yield of mass transfer.

It should be understood that, the application of the disclosure is not limited to the foregoing exemplary implementations. Those of ordinary skill in the art can make improvements or equivalent substitutions to the disclosure according to the above descriptions, and all these improvements and equivalent substitutions, however, shall all be encompassed within the protection scope of the appended claims of the disclosure.

What is claimed is:

1. A method for manufacturing a support assembly, comprising:
forming an adhesive layer on a micro light-emitting diode (LED) and/or a transient substrate;
transferring the micro LED to the transient substrate, wherein the micro LED is bonded to the transient substrate through the adhesive layer; and
forming the support assembly by etching the adhesive layer, wherein the support assembly is in a mesh shape and surrounds the micro LED.

2. The method for manufacturing the support assembly of claim 1, wherein the adhesive layer is made of organic silicide.

3. The method for manufacturing the support assembly of claim 1, wherein a silicon content of the adhesive layer ranges from 20% to 85%.

4. The method for manufacturing the support assembly of claim 3, wherein the adhesive layer is made of materials containing groups of carbon, hydrogen, and nitrogen.

5. The method for manufacturing the support assembly of claim 1, wherein the support assembly comprises a first support structure, and forming the support assembly by etching the adhesive layer comprises:
forming the first support structure of the support assembly by etching the adhesive layer.

6. The method for manufacturing the support assembly of claim 5, wherein forming the first support structure of the support assembly by etching the adhesive layer comprises:
forming the first support structure by dry etching the adhesive layer with an etching gas, wherein the etching gas is oxygen or chlorine.

7. The method for manufacturing the support assembly of claim 5, wherein the first support structure is made of silicon oxide.

8. The method for manufacturing the support assembly of claim 5, wherein the support assembly further comprises a second support structure, and the method for manufacturing the support assembly further comprises:
forming an oxide layer on the transient substrate; and
forming the second support structure by etching the oxide layer, wherein
the second support structure has a radial size smaller than a distance between two electrodes of the micro LED, and has a height greater than a height of the electrodes.

9. The method for manufacturing the support assembly of claim 8, wherein the second support structure is located between the two electrodes of the micro LED when the micro LED is bonded to the transient substrate.

10. The method for manufacturing the support assembly of claim 8, wherein the second support structure is made of silicon oxide.

11. The method for manufacturing the support assembly of claim 8, wherein the second support structure is spaced apart from the micro LED by a preset distance when the micro LED is bonded to the transient substrate.

12. A method for manufacturing a micro light-emitting diode (LED) display, comprising:
providing a substrate;
forming a plurality of micro LEDs on the substrate;
transferring the micro LEDs to a transient substrate, wherein the micro LEDs are bonded to the transient substrate through an adhesive layer;
forming a support assembly by etching the adhesive layer, wherein the support assembly is in a mesh shape and surrounds the micro LEDs; and
transferring, with a transfer structure, the micro LEDs to a display substrate.

13. The method for manufacturing the micro LED display of claim 12, wherein the transfer structure is an elastomeric stamp, and the elastomeric stamp is made of polydimethylsiloxane (PDMS).

14. The method for manufacturing the micro LED display of claim 12, wherein forming the micro LEDs comprises:
forming a first semiconductor layer on the substrate;
forming a light-emitting layer on the first semiconductor layer;
forming a second semiconductor layer on the light-emitting layer;
forming a transparent conductive layer on the second semiconductor layer;
depositing a first electrode on the first semiconductor layer; and
depositing a second electrode on the second semiconductor layer.

15. The method for manufacturing the micro LED display of claim 14, wherein forming the micro LEDs further comprises:
depositing a reflective layer on the second semiconductor layer and the transparent conductive layer.

16. The method for manufacturing the micro LED display of claim 15, wherein forming the micro LEDs further comprises:
forming a first conductive channel and a second conductive channel in the reflective layer, wherein the first conductive channel is in contact with the first semiconductor layer, and the second conductive channel is in contact with the transparent conductive layer.

17. The method for manufacturing the micro LED display of claim 16, wherein forming the first conductive channel and the second conductive channel in the reflective layer comprises:
depositing a photoresist layer on the reflective layer;
defining two openings on the photoresist layer; and
forming the first conductive channel and the second conductive channel by etching the reflective layer with the photoresist layer as a mask, wherein
an angle between a side wall of each of the two openings and the reflective layer is greater than 90 degrees.

18. The method for manufacturing the micro LED display of claim 12, wherein a silicon content of the adhesive layer ranges from 20% to 85%.

19. The method for manufacturing the micro LED display of claim 12, wherein the support assembly comprises a first support structure, and forming the support assembly by etching the adhesive layer comprises:
forming the first support structure of the support assembly by dry etching the adhesive layer with an etching gas, wherein the etching gas is oxygen or chlorine.

20. The method for manufacturing the micro LED display of claim 19, wherein the support assembly further comprises a second support structure, and the method for manufacturing the micro LED display further comprises:
forming an oxide layer on the transient substrate; and
forming the second support structure by etching the oxide layer, wherein
the second support structure has a radial size smaller than a distance between two electrodes of the micro LED, and has a height greater than a height of the electrodes.
